(19) United States
(12) Patent Application Publication
(10) Pub. No.: US 2015/0309129 A1
(43) Pub. Date: Oct. 29, 2015

(54) MAGNETIC SENSOR AND PRODUCTION METHOD THEREFOR

(71) Applicant: Murata Manufacturing Co., Ltd., Nagaokakyo-shi (JP)

(72) Inventor: ZHENHONG ZHANG, Nagaokakyo-shi (JP)

(21) Appl. No.: 14/795,251

(22) Filed: Jul. 9, 2015

Related U.S. Application Data
(63) Continuation of application No. PCT/JP2013/001629, filed on Mar. 13, 2013.

(30) Foreign Application Priority Data
Jan. 18, 2013 (JP) 2013-007348

(51) Int. Cl. G01R 33/09; G01R 33/00

(52) U.S. Cl. CPC G01R 33/09; G01R 33/0052

(57) ABSTRACT

A magnetic sensor including a pair of permanent magnets disposed at a distance from each other so that different poles are opposed to each other, and a magnetoresistive array disposed between the pair of permanent magnets. The magnetoresistive array has four magnetoresistive elements disposed so that maximum detection directions of the adjacent elements are different from one another, and the four magnetoresistive elements are connected in a bridge circuit. The pair of permanent magnets and the magnetoresistive array are disposed so that a direction substantially orthogonal to a magnetic field detection direction and a magnetic field direction between the pair of permanent magnets are neither parallel nor perpendicular to each other.

### CROSS REFERENCE TO RELATED APPLICATIONS

The present application is a continuation of International application No. PCT/JP2013/001629, filed Mar. 13, 2013, which claims priority to Japanese Patent Application No. 2013-007348, filed Jan. 18, 2013, the entire contents of each of which are incorporated herein by reference.

### FIELD OF THE INVENTION

The present invention relates to a magnetic sensor and a production method therefor, and particularly to a magnetic sensor including magnetoresistive elements, and a production method therefor.

### BACKGROUND OF THE INVENTION

With regards to general magnetoresistive elements, four magnetoresistive elements constitute a bridge circuit, a so-called wheatstone bridge circuit, using a thin film of permalloy, which is an iron (Fe)-nickel (Ni) alloy, for the purpose of increasing sensitivity and removing in-phase noise. FIG. 7A is a plan diagram showing a pattern of related magnetoresistive elements, and FIG. 7B is a circuit block diagram. The bridge circuit will be described with a Y axis direction and an X axis direction defined as shown in FIG. 7A. When a magnetic field intensity in the Y axis direction increases, resistance values of magnetoresistive elements R1 and R4 become small, and a difference of a middle-point voltage (voltage difference between V+ and V−) becomes large. On the contrary, when a magnetic field intensity in the X axis direction increases, resistance values of magnetoresistive elements R2 and R3 become small, and a sign of the difference of the middle-point voltage (voltage difference between V+ and V−) is reversed and the difference becomes small. The difference of the middle-point voltage (voltage difference between V+ and V−) allows the magnetic sensor to detect a magnetic field direction.

In PTD 1, there is proposed a magnetic sensor in which two thin-film magnets are disposed so that different poles are opposed, and a barber pole type ferromagnetic thin-film magnetoresistive element is disposed around a center of a magnetic field made by the two thin-film magnets. A technique has been described that brings about output proportional to external magnetic field change with a detection magnetic field direction set as a direction perpendicular to a direction of a bias magnetic field made by the two thin-film magnets.

PTD 1: Japanese Patent Laying-Open No. H6-148301

### SUMMARY OF THE INVENTION

However, the related magnetic sensor described in the above-described background art has the following problem.

FIG. 8A is a graph showing a relationship between the magnetic field intensity on a Y axis and a fluctuation amount of the voltage difference between V+ and V− in the related magnetic sensor, and showing general characteristics between the difference of the middle-point voltage (voltage difference between V+ and V−) and the magnetic field intensity on the Y axis. When the magnetic field intensity is 0 mT, the differential voltage is also 0 mV. However, linearity of the magnetic field intensity around 0 mT, and a differential amount of the middle-point voltage is relatively poor. Furthermore, magnetic domain walls of the magnetoresistive elements are likely to perform discontinuous motions, which causes hysteresis due to up and down of the magnetic field intensity, as shown in FIG. 8B. With regards to the Y axis direction, as the magnetic field intensity in an N to S direction is decreased from a positive value to the above-described 0 mT, the differential voltage takes a positive value beyond 0 mV when the magnetic field intensity is 0 mT. On the contrary, with regards to the Y axis direction, as the magnetic field intensity in an S to N direction is decreased from a positive value to the above-described 0 mT, the differential voltage becomes 0 mV, which is smaller than the above-mentioned positive value, when the magnetic field intensity is 0 mT. For accurate angle detection, suppression of hysteresis occurrence is demanded.

Furthermore, in the related magnetic sensor, characteristic curves in the S to N direction and in the N to S direction are symmetric to each other, as shown in FIGS. 8A and 8B. This poses a problem that whether the direction of the magnetic field is the S to N direction or in the N to S direction cannot be determined from the difference of the middle-point voltage (voltage difference between V+ and V−). When the magnetic sensor in PTD 1 is used, this problem cannot be solved.

An object of the present invention is to provide a magnetic sensor and a production method therefor that can solve the problem that in a magnetic sensor including magnetoresistive elements, favorable sensitivity characteristics cannot be obtained, and a direction of magnetic field application cannot be determined.

In order to achieve the object, a magnetic sensor according to the present invention includes a pair of permanent magnets disposed at a distance so that different poles are opposed to each other, and a magnetoresistive array disposed between the pair of permanent magnets, wherein the magnetoresistive array has four magnetoresistive elements disposed so that maximum detection directions of the adjacent elements are different from one another, and the four magnetoresistive elements are subjected to bridge circuit connection, and the pair of permanent magnets and the magnetoresistive array are disposed so that a direction substantially orthogonal to a magnetic field detection direction, and a magnetic field direction between the pair of permanent magnets are neither parallel nor perpendicular.

A production method for a magnetic sensor according to the present invention includes the steps of disposing a pair of permanent magnets at a distance so that different poles are opposed to each other, disposing a magnetoresistive array between the pair of permanent magnets, the magnetoresistive array having four magnetoresistive elements disposed so that maximum detection directions of the adjacent elements are different from one another, and the four magnetoresistive elements being subjected to bridge circuit connection, and adjusting resistance values of the four magnetoresistive elements so that with regards to a magnetic field directed from a first direction to a second direction, which is an opposite direction of the first direction, a differential voltage between opposed connecting points in the bridge circuit exhibits a positive value, and with regards to a magnetic field directed from the second direction to the first direction, the differential voltage exhibits a negative value.

According to a magnetic sensor of the present invention, favorable sensitivity characteristics can be obtained, and a magnetic field application direction can be determined.

### BRIEF DESCRIPTION OF THE DRAWINGS

FIG. 1 is a schematic diagram showing a constitution of a magnetic sensor according to a first embodiment of the present invention.

FIG. 2A is a schematic diagram showing a constitution of the magnetic sensor according to the first embodiment of the present invention.

FIG. 2B is a graph showing a relationship between a magnetic field intensity on a Y axis and a fluctuation amount of a voltage difference between V+ and V− in the magnetic sensor according to the first embodiment of the present invention.

FIG. 3A is a graph showing the relationship between the magnetic field intensity on the Y axis and the fluctuation amount of the voltage difference between V+ and V− when a pair of permanent magnets are disposed for a bridge circuit.

FIG. 3B is a diagram showing a direction of a bias magnetic field by the pair of permanent magnets.

FIG. 3C is a graph showing the relationship between the magnetic field intensity on the Y axis and the fluctuation amount of the voltage difference between V+ and V− after adjusting resistance values of magnetoresistive elements constituting the bridge circuit.

FIG. 4A is a schematic diagram showing a constitution of a modification of the magnetic sensor according to the first embodiment of the present invention.

FIG. 4B is a graph showing a relationship between the magnetic field intensity on the Y axis and the fluctuation amount of the voltage difference between V+ and V− in the modification of the magnetic sensor according to the first embodiment of the present invention.

FIG. 5A is a schematic diagram showing a bridge circuit in a different pattern.

FIG. 5B is a graph showing a relationship between the magnetic field intensity on the Y axis and the fluctuation amount of the voltage difference between V+ and V− in the bridge circuit in FIG. 5A.

FIG. 6A is a schematic diagram showing a constitution of a magnetic sensor according to a second embodiment of the present invention.

FIG. 6B is a graph showing a relationship between a magnetic field intensity on a Y axis and a fluctuation amount of a voltage difference between V+ and V− in the magnetic sensor according to the second embodiment of the present invention.

FIG. 7A is a plan diagram showing a pattern of related magnetoresistive elements.

FIG. 7B is a circuit block diagram of FIG. 7A.

FIG. 8A is a graph showing a relationship between a magnetic field intensity on a Y axis and a fluctuation amount of a voltage difference between V+ and V− in the related magnetic sensor.

FIG. 8B is a graph showing the relationship between the magnetic field intensity on the Y axis and the fluctuation amount of the voltage difference between V+ and V− for describing hysteresis in the related magnetic sensor.

### DETAILED DESCRIPTION OF THE PREFERRED EMBODIMENTS

Referring to the drawings, preferable embodiments of the present invention will be described in detail.

### First Embodiment

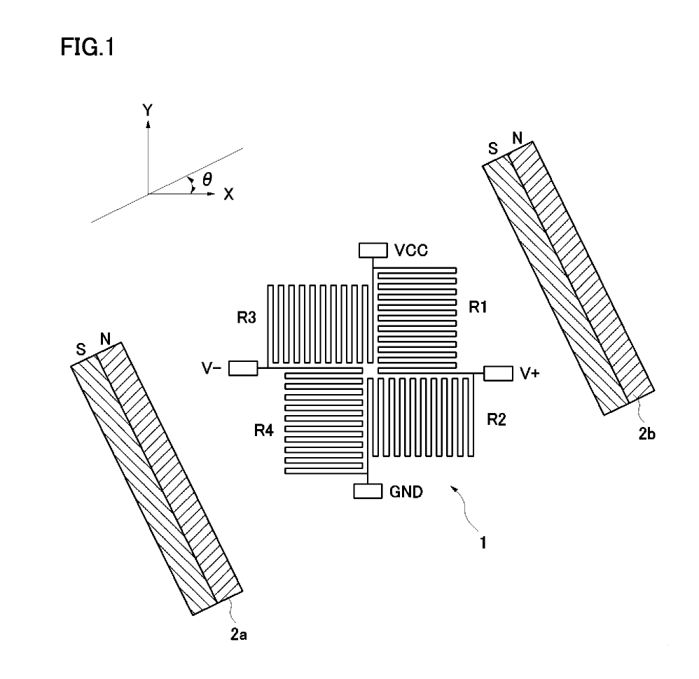

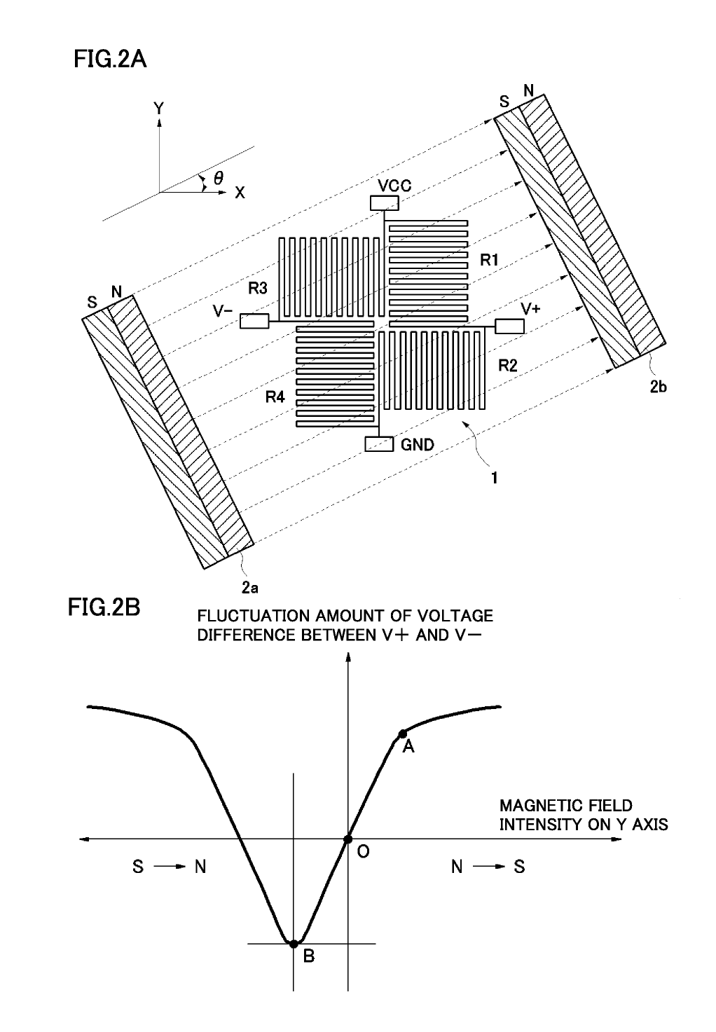

Firstly, a magnetic sensor and a production method therefor according to a first embodiment of the present invention will be described. FIG. 1 is a schematic diagram showing a constitution of the magnetic sensor according to the first embodiment of the present invention. FIG. 2A is a schematic diagram showing the constitution of the magnetic sensor according to the first embodiment of the present invention. FIG. 2B is a graph showing a relationship between a magnetic field intensity on a Y axis and a fluctuation amount of a voltage difference between V+ and V− in the magnetic sensor according to the first embodiment of the present invention.

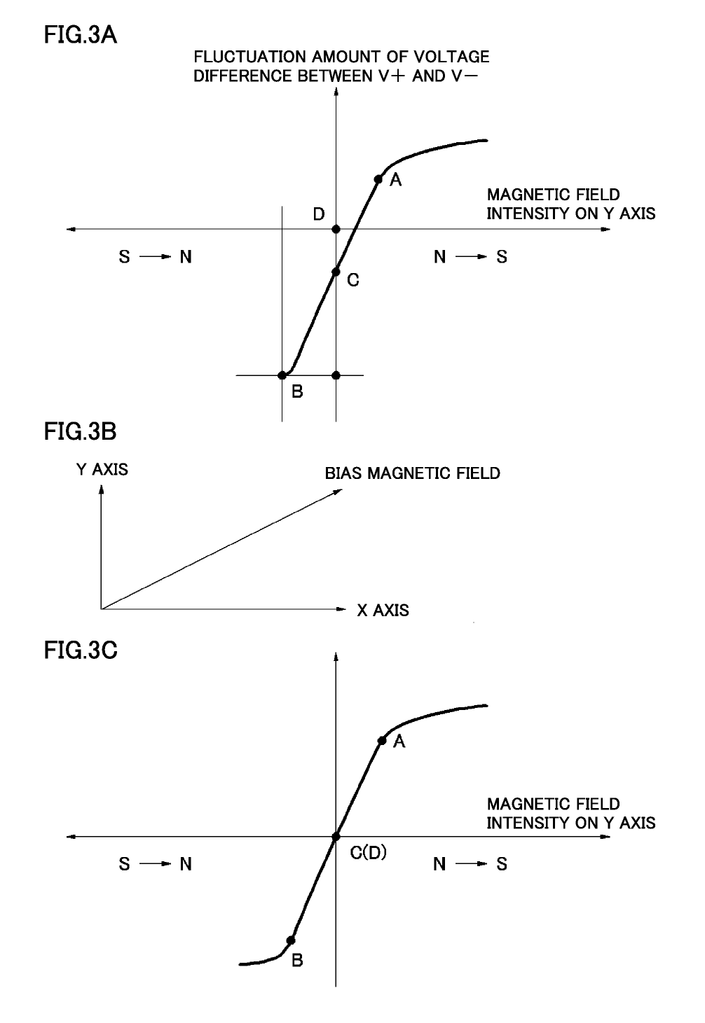

FIG. 3A is a graph showing the relationship between the magnetic field intensity on the Y axis and the fluctuation amount of the voltage difference between V+ and V− when a pair of permanent magnets are disposed for a bridge circuit. FIG. 3B is a diagram showing a direction of a bias magnetic field by the pair of permanent magnets. FIG. 3C is a graph showing the relationship between the magnetic field intensity on the Y axis and the fluctuation amount of the voltage difference between V+ and V− after resistance values of magnetoresistive elements constituting the bridge circuit are adjusted.

The magnetic sensor according to the present invention includes a pair of permanent magnets 2a and 2b disposed at a distance so that different poles are opposed to each other, that is, an N pole and an S pole are opposed, and a magnetoresistive array 1 disposed between pair of permanent magnets 2a and 2b. In magnetoresistive array 1, four magnetoresistive elements R1 to R4 each formed of a magnetic body thin film to detect a direction of a magnetic field are disposed so that maximum detection directions of the adjacent elements are different from one another, and four magnetoresistive elements R1 and R4 are subjected to bridge-circuit connection.

As shown in FIG. 1, magnetoresistive array 1 is disposed so that an X axis direction coincides with longer sides of patterns of magnetoresistive elements R1 and R4, and a Y axis direction coincides with longer sides of patterns of magnetoresistive elements R2 and R3. That is, magnetoresistive elements R1 and R4 are each disposed in a zigzag shape so that a direction parallel to the X axis direction is the maximum detection direction, and magnetoresistive elements R2 and R3 are each disposed in a zigzag shape so that a direction parallel to the Y axis direction is the maximum detection direction.

Pair of permanent magnets 2a and 2b, and magnetoresistive array 1 are disposed so that a direction substantially orthogonal to a magnetic field detection direction, and a magnetic field direction between pair of permanent magnets 2a and 2b are neither parallel nor perpendicular. That is, as shown in FIG. 2A, pair of permanent magnets 2a and 2b, and magnetoresistive array 1 are disposed so that a line of magnetic force directed from the N pole of permanent magnet 2a to the S pole of permanent magnet 2b, and the X axis direction form a predetermined angle θ. This angle θ is selected from a range of 5° to 85°.

When angle θ is small, a C point as a central point in FIG. 3C is moved to a B point side, so that a range of magnetic field detection in an N to S direction is enlarged, while a range of magnetic field detection in an S to N direction is reduced. Thus, a case where the magnetic sensor performs only the detection in the N to S direction is advantageous.

When angle θ is large, the C point as the central point in FIG. 3C is moved to a A point side, so that the range of the magnetic field detection in the S to N direction is enlarged, while the range of the magnetic field detection in the N to S direction becomes narrow. Thus, a case where the magnetic sensor performs only the detection in the S to N direction is advantageous.

Disposing permanent magnets 2a and 2b at both ends of magnetoresistive elements allows the bias magnetic field to be applied both in the X axis direction and in the Y axis direction. A bias magnetic field intensity on the X axis is a saturation magnetic field intensity HS, and even when an external magnetic field to be detected is absent, a magnetization direction of the magnetoresistive elements coincides with the X axis direction, and discontinuous motions of magnetic domain walls are decreased, so that hysteresis is also decreased. Preferably, a bias magnetic field intensity in the Y axis direction is set to half of saturation magnetic field intensity HS. FIG. 3B shows partial amounts in the X axis direction and in the Y axis direction by a vector of the bias magnetic field by pair of permanent magnets 2a and 2b at this time. Above-described angle θ at which the magnetic field intensity in the Y axis direction becomes ½ of the magnetic field intensity in the X axis direction is substantially 26.5°. Saturation magnetic field intensity HS can be decided by sizes (a length, a width, and a thickness) of each of the magnetoresistive elements.

In a state where the external magnetic field is not applied, a magnetic field intensity H at a center of the magnetoresistive elements is decided by both permanent magnets 2a and 2b. When pair of permanent magnets 2a and 2b are disposed for the bridge circuit, the bias magnetic field of pair of permanent magnets 2a and 2b decreases magnetic domains, and the magnetic domain walls are diminished, so that a magnetic state of the magnetoresistive elements constituting the bridge circuit is stabilized. The bias magnetic field by pair of permanent magnets 2a and 2b results in the characteristics of the magnetic field intensity on the Y axis and the voltage difference between V+ and V− as shown in FIG. 3A. Since the bias magnetic field in the X axis direction is intensive, the difference of the middle-point voltage (voltage difference between V+ and V−) at the C point takes a negative value. When the magnetic field is applied only in the Y axis direction, a point of “0” mT is the C point. A curve of the difference of the middle-point voltage (voltage difference between V+ and V−) by the magnetic field in the N to S direction is CA, and a curve of the difference of the middle-point voltage (voltage difference between V+ and V−) by the magnetic field in the S to N direction is CB. In FIG. 3A, with regards to the magnetic field in the N to S direction, the voltage difference changes from a point C to a point A. That is, the voltage difference of the middle-point voltage (V+ and V−) in the bridge circuit changes from a negative value to a positive value. In FIG. 3A, with regards to the magnetic field in the S to N direction, the voltage difference changes from point C to a point B. That is, the voltage difference between V+ and V− changes from a negative value to a smaller negative value.

In the magnetic sensor of the present embodiment, the resistance values of above-described four magnetoresistive elements R1 to R4 may be adjusted so that the difference of the middle-point voltage (voltage difference between V+ and V−) in the above-described bridge circuit exhibits a positive value with regards to a magnetic field directed from a positive direction on the Y axis as one example of a first direction to a negative direction on the Y axis as one example of a second direction, which is an opposite direction to the first direction, and the above-described middle-point voltage difference exhibits a negative value with regards to a magnetic field directed from the negative direction on the Y axis to the position direction on the Y axis.

That is, by adjusting the resistance values of magnetoresistive elements R1 to R4, the C point of the “0” mt point in FIG. 3A is moved to a D point, and an offset voltage can be zero as shown in the characteristics in FIG. 3C.

When the magnetic field in the N to S direction is applied to the Y axis, the difference of the middle-point voltage (voltage difference between V+ and V−) in the bridge circuit exhibits a curve from the C point to the A point on a plus side, and when the magnetic field in the S to N direction is applied, the difference exhibits a curve from the C point to the B point on a minus side.

The above-described setting results in the characteristics of the magnetic field intensity on the Y axis and the voltage difference between V+ and V− as shown in FIG. 3C. In FIG. 3C, with regards to the magnetic field in the N to S direction, the voltage difference changes from point C to point A. That is, the voltage difference between V+ and V− changes from zero to a positive value. With regards to the magnetic field in the S to N direction, the voltage difference changes from point C to point B. That is, the voltage difference between V+ and V− changes from zero to a negative value.

According to the magnetic sensor of the present embodiment, with regards to the magnetic field in the N to S direction, the voltage difference between V+ and V− of the bridge circuit exhibits a positive value, and with regards to the magnetic field in the S to N direction, the voltage difference between V+ and V− in the bridge circuit exhibits a negative value. Thus, the magnetic sensor that enables the magnetic field direction to be determined from the difference of the middle-point voltage in the bridge circuit can be obtained.

Furthermore, according to the magnetic sensor of the present embodiment, the curves of CA and CB are well-balanced, and linearity of sensitivity characteristics is largely improved with the C point used as a center point. Furthermore, the hysteresis of the magnetoresistive elements due to up and down of the magnetic field application is almost eliminated.

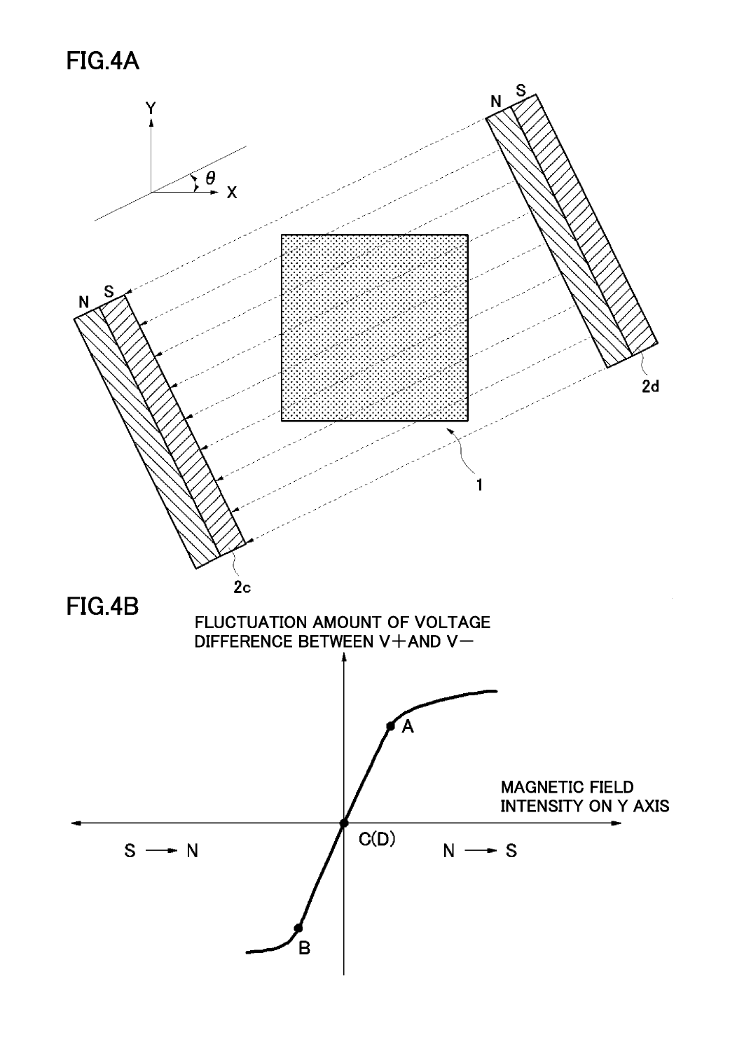

The above-described magnetic sensor according to the first embodiment can also be constituted as follows. FIG. 4A is a schematic diagram showing a constitution of a modification of the magnetic sensor according to the first embodiment of the present invention. FIG. 4B is a graph showing the relationship between the magnetic field intensity on the Y axis and the fluctuation amount of the voltage difference between V+ and V− in a magnetic sensor according to the modification of the first embodiment of the present invention.

The magnetic sensor shown in FIG. 4A is different in that in place of pair of permanent magnets 2a and 2b of the magnetic sensor shown in FIG. 1A, a pair of permanent magnets 2c and 2d whose S pole and N pole are replaced is used. In this modification, a shape, disposition, and the like of magnetoresistive elements constituting a magnetoresistive array 1 and a bridge circuit are the same as magnetoresistive array 1 shown in FIG. 1A. As shown in FIG. 4B, the magnetic sensor disposed in this manner exhibits the same characteristics as the magnetic field intensity on the Y axis and the fluctuation amount of the voltage difference between V+ and V− in FIG. 3C.

In the above-described modification as well, as in the above-described magnetic sensor according to the first embodiment, the linearity of sensitivity characteristics is largely improved, and the magnetic field application direction of an S to N direction or an N to S direction can be determined, and hysteresis of the magnetoresistive elements due to up and down of the magnetic field application is almost eliminated.

### Second Embodiment

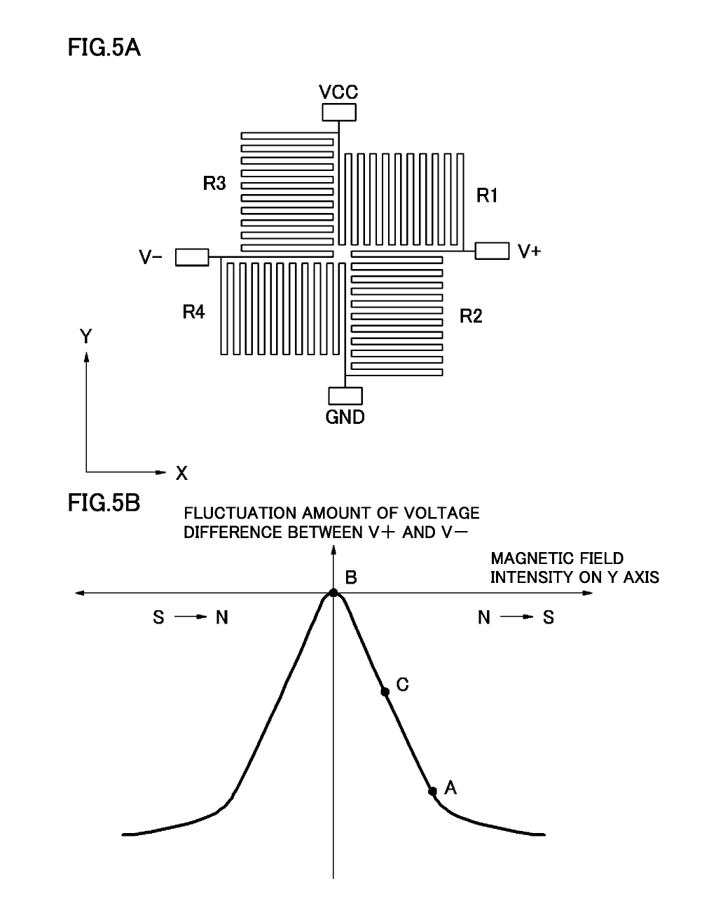

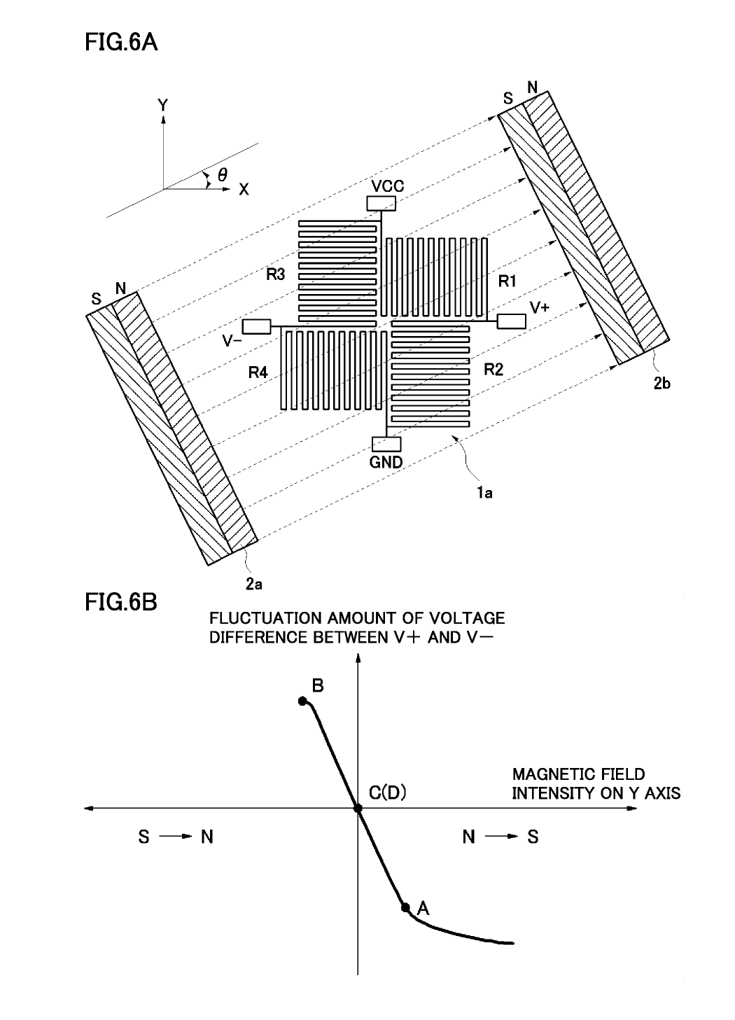

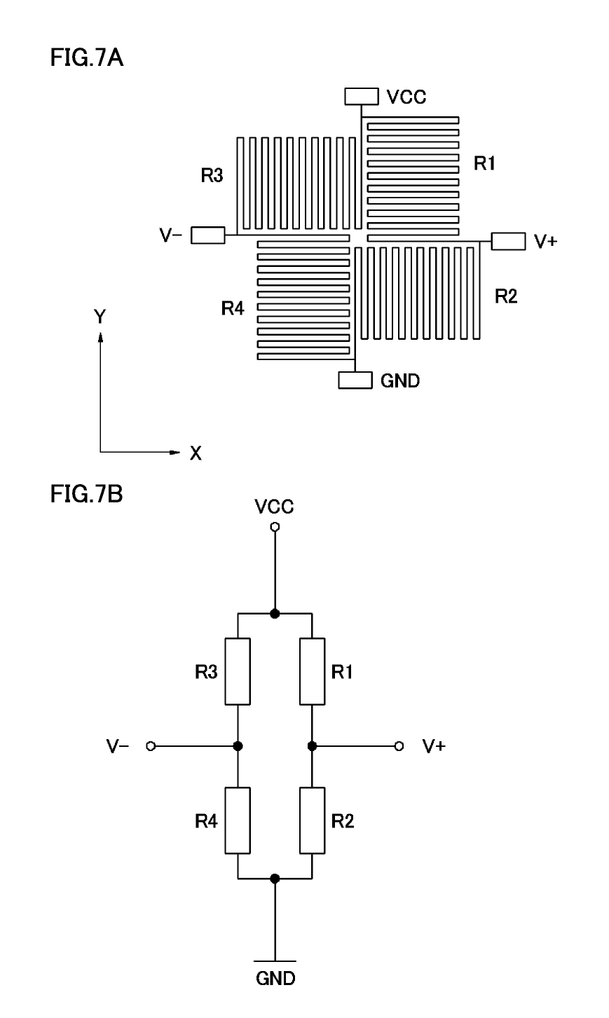

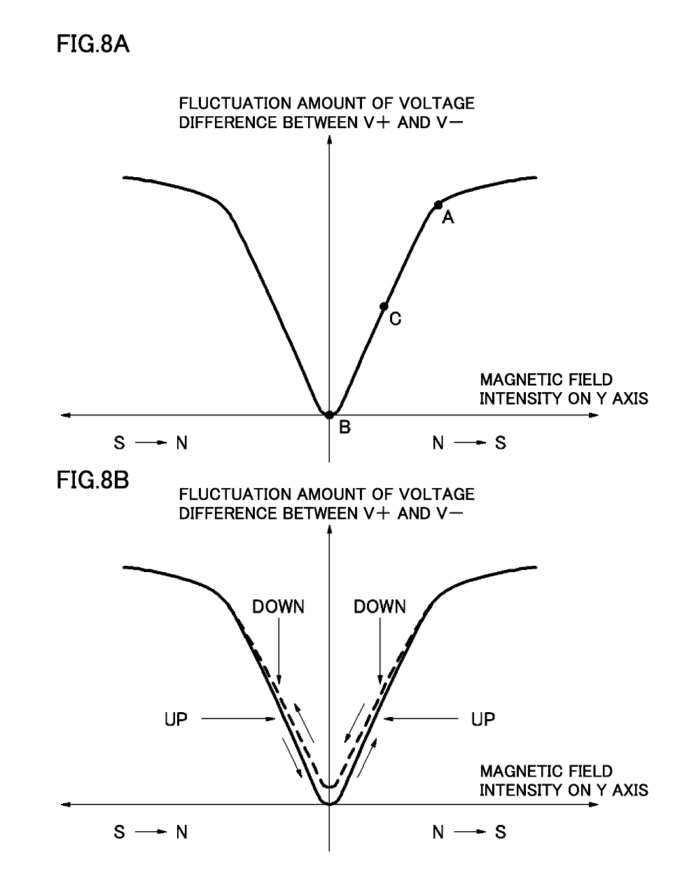

Next, a magnetic sensor and a production method therefor according to a second embodiment of the present invention will be described. FIG. 5A is a schematic diagram showing a bridge circuit in a different pattern, and FIG. 5B is a graph showing a relationship between a magnetic field intensity on a Y axis and a fluctuation amount of a voltage difference between V+ and V− in this bridge circuit. FIG. 6A is a schematic diagram showing a constitution of the magnetic sensor according to the second embodiment of the present invention. FIG. 6B is a graph showing a relationship between a magnetic field intensity on a Y axis and a fluctuation amount of a voltage difference between V+ and V− in the magnetic sensor according to the second embodiment of the present invention.

FIG. 5A shows the bridge circuit in the different pattern from the pattern of magnetoresistive array 1 of the magnetic sensor of the first embodiment shown in FIG. 1. That is, the bridge circuit in FIG. 5A is formed in a pattern obtained by laterally reversing the pattern of magnetoresistive array 1 of the magnetic sensor shown in FIG. 1. As shown in FIG. 5A, magnetoresistive elements R1 and R4 are each disposed in a zigzag shape so that a direction parallel to the Y axis direction is a maximum detection direction, and magnetoresistive elements R2 and R3 are each disposed in a zigzag shape so that a direction parallel to an X axis direction is the maximum detection direction.

In the case of the bridge circuit in the above-described pattern, characteristics of the magnetic field intensity on the Y axis and the difference of a middle-point voltage (voltage difference between V+ and V−) can be seen from FIG. 5B. With regards to a Y axis direction, when the magnetic field intensity in an N to S direction is increased from 0 mT, the difference of the middle-point voltage (voltage difference between V+ and V−) decreases from a point B to a point C, and further a point A while exhibiting negative values. With regards to the Y axis direction, when the magnetic field intensity in an S to N direction is increased from 0 mT, the difference of the middle-point voltage (voltage difference between V+ and V−) decreases from point B while exhibiting negative values. In FIG. 5B, characteristic curves in the S to N direction and in the N to S direction are symmetrical to each other.

The magnetic sensor of the present embodiment uses the bridge circuit in the above-described pattern. The magnetic sensor of the present embodiment, as shown in FIG. 6A, includes a pair of permanent magnets 2a and 2b disposed at a distance so that different poles are opposed to each other, that is, so that an N pole and an S pole are opposed to each other, and a magnetoresistive array 1a disposed between pair of permanent magnets 2a and 2b. In magnetoresistive array 1a, four magnetoresistive elements R1 to R4 each formed of a magnetic body thin film to detect a direction of a magnetic field are disposed so that maximum detection directions of the adjacent elements are different from one another, and four magnetoresistive elements R1 and R4 are subjected to bridge-circuit connection.

As shown in FIG. 6A, magnetoresistive array 1a is disposed so that the X axis direction coincides with longer sides of patterns of magnetoresistive elements R2 and R3, and the Y axis direction coincides with longer sides of patterns of magnetoresistive elements R1 and R4. That is, magnetoresistive elements R2 and R3 are each disposed in a zigzag shape so that a direction parallel to the X axis direction is the maximum detection direction, and magnetoresistive elements R1 and R4 are each disposed in a zigzag shape so that a direction parallel to the Y axis direction is the maximum detection direction.

Pair of permanent magnets 2a and 2b, and magnetoresistive array 1a are disposed so that a direction substantially orthogonal to a magnetic field detection direction of the magnetic sensor, and a magnetic field direction between pair of permanent magnets 2a and 2b are neither parallel nor perpendicular. As shown in FIG. 6A, pair of permanent magnets 2a and 2b, and magnetoresistive array 1a are disposed so that a line of magnetic force directed from the N pole of permanent magnet 2a to the S pole of permanent magnet 2b, and the X axis direction form a predetermined angle θ. This angle θ is selected from a range of 5° to 85°. Preferably, the magnetic field intensity in the Y axis direction is set to ½ of the magnetic field intensity in the X axis direction. Above-described angle θ at this time is almost 26.5°.

In the present embodiment, resistance values of above-described four magnetoresistive elements R1 to R4 can be adjusted so that the differential voltage between opposed connecting points V+ and V− in the above-described bridge circuit exhibits a positive value with regards to a magnetic field directed from a negative direction on the Y axis as one example of a first direction to a positive direction on the Y axis as one example of a second direction, which is an opposite direction to the first direction, and the above-described differential voltage exhibits a negative value with regards to a magnetic field directed from the positive direction on the Y axis to the negative direction on the Y axis.

The above-described setting results in the characteristics of the magnetic field intensity on the Y axis and the voltage difference between V+ and V− as shown in FIG. 6B. In FIG. 6B, with regards to the magnetic field in the N to S direction, the voltage difference changes from a point C to point A. That is, the difference of the middle-point voltage (voltage difference between V+ and V−) changes from zero to a negative value. With regards to the magnetic field in the S to N direction, the voltage difference changes from point C to point B. That is, the difference of the middle-point voltage (voltage difference between V+ and V−) changes from zero to a positive value.

According to the magnetic sensor of the present embodiment, the voltage difference between V+ and V− in the bridge circuit exhibits a negative value with regards to the magnetic field in the N to S direction, and the voltage difference between V+ and V− in the bridge circuit exhibits a positive value with regards to the magnetic field in the S to N direction. Thus, the magnetic sensor that enables the magnetic field direction to be determined from the difference of the middle-point voltage in the bridge circuit can be obtained.

According to the magnetic sensor of the present embodiment, as in the magnetic sensor according to the first embodiment, linearity of sensitivity characteristics is largely improved, and the magnetic field application direction of the S to N direction or the N to S direction can be determined, and hysteresis of the magnetoresistive elements due to up and down of the magnetic field application is almost eliminated.

### Example

An example of the present invention will be described. For each magnetoresistive element with permanent magnets disposed at both ends, one example of a particular pattern as shown in FIG. 1 will be described. A length of the rectangular pattern constituting the bridge circuit is 230 μm, and a width thereof is 9 μm. A pattern interval is 2 μm. Magnetoresistive elements R1, R2, R3, and R4 are each constituted by connecting 21 rectangular patterns. A thickness of an element thin film is 400 nm.

The pair of permanent magnets each have a length of 1.5 mm, a width of 0.6 mm, and a thickness of 0.2 mm. The permanent magnets are each a ferrite magnet. An angle between the permanent magnets and the X axis direction is 154°. Accordingly, the angle formed by the line of magnetic force directed from the N pole to the S pole of the opposed permanent magnets, and the X axis direction is 26°. The permanent magnets are fixed and disposed on the same substrate in an assembly process (sealing) of the magnetoresistive elements or the magnetic sensor.

Obviously, the present invention is not limited to the above-described embodiments and the above-described example, various modifications can be made within the scope of the invention described in the claims, and these modifications are included in the scope of the invention.

This application claims a right to priority on the basis of Japanese Patent Application No. 2013-7348 filed on Jan. 18, 2013, all the subject matter of which is incorporated herein.

As practical use examples of the present invention, rotation detection of a water meter and a gas meter, a magnetic current sensor, an encoder of a motor and the like can be considered.

### REFERENCE SIGNS LIST

1, 1a magnetoresistive array
2a, 2b, 2c, 2d permanent magnet
R1 to R4 magnetoresistive element

1. A magnetic sensor comprising:
a pair of permanent magnets disposed at a distance from each other and oriented so that different poles are opposed to each other; and
a magnetoresistive array disposed between said pair of permanent magnets, wherein
said magnetoresistive array has four magnetoresistive elements disposed so that maximum detection directions of adjacent elements of said four magnetoresistive elements are different from one another, and
said pair of permanent magnets and said magnetoresistive array are disposed so that a direction substantially orthogonal to a magnetic field detection direction and a magnetic field direction between said pair of permanent magnets are neither parallel nor perpendicular to each other.

2. The magnetic sensor according to claim 1, wherein said four magnetoresistive elements are connected in a bridge circuit.

3. The magnetic sensor according to claim 2, wherein said four magnetoresistive elements have resistance values such that a differential voltage between opposed connecting points in said bridge circuit exhibits a positive value with respect to a magnetic field directed from a first direction to a second direction opposite to said first direction.

4. The magnetic sensor according to claim 3, wherein said resistance values of said four magnetoresistive elements are such that the differential voltage between opposed connecting points in said bridge circuit exhibits a negative value with respect to a magnetic field directed from said second direction to said first direction.

5. The magnetic sensor according to claim 3, wherein said differential voltage monotonically increases while exhibiting said positive value.

6. The magnetic sensor according to claim 4, wherein said differential voltage monotonically decreases while exhibiting said negative value.

7. The magnetic sensor according to claim 1, wherein
a first set of two diagonally opposed magnetoresistive elements of said four magnetoresistive elements each have a zigzag constitution in which a plurality of regions along a direction substantially perpendicular to the magnetic field detection direction are disposed parallel at predetermined intervals, are joined so as to be sequentially folded back, and are electrically connected in series, and
a second set of two diagonally opposed magnetoresistive elements of said four magnetoresistive elements each have a zigzag constitution in which a plurality of regions along a direction substantially parallel to said magnetic field detection direction are disposed parallel at predetermined intervals, are joined so as to be sequentially folded back, and are electrically connected in series.

8. The magnetic sensor according to claim 7, wherein an angle formed between the direction substantially perpendicular to said magnetic field detection direction and the magnetic field direction between said pair of permanent magnets is in a range of 5 degrees to 85 degrees.

9. The magnetic sensor according to claim 8, wherein said angle is substantially 26.5 degrees.

10. The magnetic sensor according to claim 3, wherein said first direction and said second direction are parallel to said magnetic field detection direction.

11. The magnetic sensor according to claim 3, wherein said first direction and said second direction are parallel to the direction orthogonal to said magnetic field detection direction.

12. A production method for a magnetic sensor, the production method comprising:
disposing a pair of permanent magnets at a distance from each other so that different poles are opposed to each other;
disposing a magnetoresistive array between said pair of permanent magnets, the magnetoresistive array having four magnetoresistive elements disposed so that maximum detection directions of adjacent elements are different from one another, and said four magnetoresistive elements connected in a bridge circuit; and
adjusting respective resistance values of said four magnetoresistive elements so that with regards to a magnetic field directed from a first direction to a second direction opposite to said first direction, a differential voltage between opposed connecting points in said bridge circuit exhibits a positive value, and with regards to a magnetic field directed from said second direction to said first direction, said differential voltage exhibits a negative value.

13. The production method for a magnetic sensor according to claim 12, wherein said respective resistance values of said four magnetoresistive elements are adjusted so that said differential voltage monotonically increases while exhibiting said positive value.

14. The production method for a magnetic sensor according to claim 12, wherein said respective resistance values of said four magnetoresistive elements are adjusted so that said differential voltage monotonically decreases while exhibiting said negative value.

15. The production method for a magnetic sensor according to claim 12, wherein:
a first set of two diagonally opposed magnetoresistive elements of said four magnetoresistive elements each have a zigzag constitution in which a plurality of regions along a direction substantially perpendicular to the magnetic field detection direction are disposed parallel at predetermined intervals, are joined so as to be sequentially folded back, and are electrically connected in series, and
a second set of two diagonally opposed magnetoresistive elements of said four magnetoresistive elements each have a zigzag constitution in which a plurality of regions along a direction substantially parallel to said magnetic field detection direction are disposed parallel at predetermined intervals, are joined so as to be sequentially folded back, and are electrically connected in series.

16. The production method for a magnetic sensor according to claim 12, wherein said magnetoresistive array is disposed between said pair of permanent magnets such that an angle formed between the direction substantially perpendicular to said magnetic field detection direction and the magnetic field direction between said pair of permanent magnets is in a range of 5 degrees to 85 degrees.

17. The production method for a magnetic sensor according to claim 16, wherein said angle is substantially 26.5 degrees.

18. The production method for a magnetic sensor according to claim 12, wherein said first direction and said second direction are parallel to said magnetic field detection direction.

19. The production method for a magnetic sensor according to claim 12, wherein said first direction and said second direction are parallel to the direction orthogonal to said magnetic field detection direction.
